(19) United States
(12) Patent Application Publication
(10) Pub. No.: US 2024/0194703 A1
(43) Pub. Date: Jun. 13, 2024

(54) PHOTOELECTRIC SENSOR, IMAGE SENSOR AND ELECTRONIC DEVICE

(71) Applicants: BEIJING BOE SENSOR TECHNOLOGY CO., LTD., Beijing (CN); BOE TECHNOLOGY GROUP CO., LTD., Beijing (CN)

(72) Inventors: Shoujin CAI, Beijing (CN); Cheng LI, Beijing (CN); Jie ZHANG, Beijing (CN); Jin CHENG, Beijing (CN); Dexi KONG, Beijing (CN); Tiansheng LI, Beijing (CN); Chuncheng CHE, Beijing (CN); Yingzi WANG, Beijing (CN)

(21) Appl. No.: 17/789,552

(22) PCT Filed: Jun. 25, 2021
(86) PCT No.: PCT/CN2021/102330

§ 371 Date: Jun. 28, 2022

(51) Int. Cl. H01L 27/146

(52) U.S. Cl. CPC H01L 27/14612; H01L 27/14636; H01L 27/14643

(57) ABSTRACT

A photoelectric sensor, an image sensor and an electronic device are disclosed. The photoelectric sensor includes a base substrate, a driving circuit and a photoelectric converter, the driving circuit and the photoelectric converter are located on the base substrate; the photoelectric converter includes a first electrode and a photoelectric conversion layer, and the photoelectric conversion layer is located at a side of the first electrode away from the base substrate, the driving circuit includes a reset sub-circuit, the reset sub-circuit includes a first source electrode and a first drain electrode, the first electrode and the first drain electrode are integrated into a same electrode and arranged in a same layer as the first source electrode.

### TECHNICAL FIELD

The embodiments of the present disclosure relate to a photoelectric sensor, an image sensor and an electronic device.

### BACKGROUND

With the continuous development of digital technology, semiconductor manufacturing technology and network technology, the demand for image sensors in the market is growing and diversified. Sensors can be divided into charge coupled devices (CCD) and complementary metal oxide semiconductor devices (CMOS).

Charge coupled device (CCD) is supported by a high-sensitivity semiconductor material, which can convert light into electric charge, and then convert the electric charge into a digital signal through an analog-to-digital converter chip. The digital signal is compressed and stored in memory. Charge coupled device (CCD) is formed of a plurality of photosensitive units. Upon a surface of the charge coupled device (CCD) being illuminated by light, each of the photosensitive units will reflect the received light on the electric charge, and the signals generated by all the photosensitive units will be combined together to form a complete picture.

Complementary metal oxide semiconductor device (CMOS) mainly uses elements such as silicon or germanium to form a PIN photodiode to convert an optical signal into an electrical signal, and the electrical signal change with the change of light. Compared with the charge coupled device (CCD), the complementary metal oxide semiconductor device (CMOS) has the advantages of small size, low power consumption and low cost.

### SUMMARY

Embodiments of the present disclosure provide a photoelectric sensor, an image sensor and an electronic device. By arranging the first drain electrode of the reset sub-circuit and the first electrode of the photoelectric converter in the same layer and connecting the first drain electrode and the first electrode into a whole, the photoelectric sensor can save a plurality of film structures and a plurality of exposure processes, and further reduce the cost and the volume of the photoelectric sensor.

At least one embodiment of the present disclosure provides a photoelectric sensor, and the photoelectric sensor comprises a base substrate: a driving circuit, located on the base substrate: a photoelectric converter, located on the base substrate, and the photoelectric converter comprises a first electrode and a photoelectric conversion layer, and the photoelectric conversion layer is located at a side of the first electrode away from the base substrate, and the driving circuit comprises a reset sub-circuit, the reset sub-circuit comprises a first source electrode and a first drain electrode, the first electrode and the first drain electrode are integrated into a same electrode and arranged in a same layer as the first source electrode.

For example, in the photoelectric sensor provided by an embodiment of the present disclosure, an orthographic projection of the first electrode of the photoelectric converter on the base substrate is spaced apart from an orthographic projection of the first source electrode on the base substrate.

For example, in the photoelectric sensor provided by an embodiment of the present disclosure, the reset sub-circuit comprises a reset transistor, and the reset transistor comprises a first active layer, and an overlapping area of an orthographic projection of the photoelectric conversion layer and an orthographic projection of the first active layer on the base substrate is less than ½ of an area of the orthographic projection of the first active layer on the base substrate.

For example, in the photoelectric sensor provided by an embodiment of the present disclosure, an orthographic projection of the photoelectric conversion layer on the base substrate falls within a range of an orthographic projection of the first electrode on the base substrate.

For example, in the photoelectric sensor provided by an embodiment of the present disclosure, the driving circuit further comprises a signal reading sub-circuit and a signal amplifying sub-circuit, an orthographic projection of the signal reading sub-circuit on the base substrate, an orthographic projection of the signal amplifying sub-circuit on the base substrate and an orthographic projection of the reset sub-circuit on the base substrate are sequentially arranged in a first direction, and an orthographic projection of the driving circuit on the base substrate and an orthographic projection of the photoelectric converter on the base substrate are sequentially arranged in a second direction.

For example, in the photoelectric sensor provided by an embodiment of the present disclosure, the signal reading sub-circuit comprises a signal reading transistor, the signal amplifying sub-circuit comprises a signal amplifying transistor, the signal reading transistor comprises a second active layer, the signal amplifying transistor comprises a third active layer, an orthographic projection of the second active layer on the base substrate is spaced apart from an orthographic projection of the photoelectric converter on the base substrate, and an orthographic projection of the third active layer on the base substrate is spaced apart from the orthographic projection of the photoelectric converter on the base substrate.

For example, in the photoelectric sensor provided by an embodiment of the present disclosure, the photoelectric conversion layer comprises a bisector extending in the first direction, and the driving circuit is located at a side of the bisector in the second direction.

For example, in the photoelectric sensor provided by an embodiment of the present disclosure, the reset sub-circuit further comprises a first control electrode, the signal reading sub-circuit comprises a second control electrode, a second source electrode and a second drain electrode, and the signal amplifying sub-circuit comprises a third control electrode, a third source electrode and a third drain electrode, the third drain electrode is connected with the second source electrode, and the first drain electrode is connected with the third control electrode.

For example, the photoelectric sensor provided by an embodiment of the present disclosure further comprises: a power line, extending in the second direction and configured to be connected with the first source electrode and the third source electrode: a data reading control line, extending in the first direction and configured to be connected with the second control electrode: a reset control line, extending in the first direction and configured to be connected with the first control electrode: and a data signal line, extending in the second direction and configured to be connected with the second drain electrode.

For example, in the photoelectric sensor provided by an embodiment of the present disclosure, an orthographic projection of the reset control line on the base substrate partially overlaps with an orthographic projection of the photoelectric conversion layer on the base substrate, the photoelectric conversion layer comprises a bisector extending in the first direction, and the reset control line is located at a side of the bisector close to the data reading control line.

For example, the photoelectric sensor provided by an embodiment of the present disclosure further comprises: a reset connection block, extending along the second direction and located between the power line and the photoelectric conversion layer, and the reset connection block is respectively connected with the reset control line and the first control electrode.

For example, in the photoelectric sensor provided by an embodiment of the present disclosure, the photoelectric converter further comprises: a conductive protection layer, located at a side of the photoelectric conversion layer away from the first electrode: an insulating layer, located at a side of the conductive protection layer away from the base substrate: a first passivation layer, located at a side of the insulating layer away from the conductive protection layer; and a second electrode, located at a side of the first passivation layer away from the base substrate, and the photoelectric sensor further comprises a first via hole located in the insulating layer and the first passivation layer, and the second electrode is connected with the conductive protection layer through the first via hole.

For example, the photoelectric sensor provided by an embodiment of the present disclosure further comprises: a second passivation layer, located at a side of the second electrode away from the base substrate; and an electrostatic protection layer, located at a side of the second passivation layer away from the second electrode.

For example, in the photoelectric sensor provided by an embodiment of the present disclosure, a material of the conductive protection layer is a transparent conductive oxide, and a material of the second electrode is a transparent conductive oxide.

For example, in the photoelectric sensor provided by an embodiment of the present disclosure, the photoelectric conversion layer comprises an N-type semiconductor layer, an intrinsic semiconductor layer and a P-type semiconductor layer.

At least one embodiment of the present disclosure further provides an image sensor, and the image sensor comprises a plurality of photoelectric sensors, and each of the photoelectric sensors is the photoelectric sensor according to any one of the above embodiments.

For example, in the image sensor provided by an embodiment of the present disclosure, the plurality of photoelectric sensors are arranged in an array.

At least one embodiment of the present disclosure further provides an electronic device, which comprises the image sensor.

### BRIEF DESCRIPTION OF THE DRAWINGS

In order to more clearly explain the technical solution of the embodiments of the present disclosure, the following will briefly introduce the drawings of the embodiments. Obviously, the drawings in the following description only relate to some embodiments of the present disclosure, but not limit the present disclosure.

FIG. 1 is a schematic plan view of a photoelectric sensor:

FIG. 2 is a schematic cross-sectional view of the photoelectric sensor shown in FIG. 1:

FIG. 3 is a schematic plan view of a photoelectric sensor according to an embodiment of the present disclosure:

FIG. 4 is a schematic cross-sectional view of a photoelectric sensor provided by an embodiment of the present disclosure along a line AA in FIG. 3:

FIG. 5 is an equivalent schematic diagram of a driving circuit in a photoelectric sensor according to an embodiment of the present disclosure:

FIG. 6 is a schematic diagram of a photoelectric conversion layer provided by an embodiment of the present disclosure:

FIG. 7 is a schematic diagram of an image sensor according to an embodiment of the present disclosure; and

FIG. 8 is a schematic diagram of an electronic device according to an embodiment of the present disclosure.

### DETAILED DESCRIPTION

In order to make objects, technical details and advantages of embodiments of the present disclosure clear, the technical solutions of the embodiments will be described in a clearly and fully understandable way in connection with the related drawings. It is apparent that the described embodiments are just a part but not all of the embodiments of the present disclosure. Based on the described embodiments herein, those skilled in the art can obtain, without any inventive work, other embodiment(s) which should be within the scope of the present disclosure.

Unless otherwise defined, the technical terms or scientific terms used in the present disclosure shall have their ordinary meanings as understood by those with ordinary skills in the field to which the present disclosure belongs. The words “first”, “second” and the like used in the present disclosure do not indicate any order, quantity or importance, but are only used to distinguish different components. Words such as “comprising” or “including” refer to that the elements or objects appearing before the word cover the listed elements or objects appearing after the word and their equivalents, without excluding other elements or objects.

Complementary metal oxide semiconductor device (CMOS) can also be divided into a passive pixel sensor and an active pixel sensor; the active pixel sensor can improve image quality and reduce noise interference, and the development of thin film transistor technology is becoming more and more mature. The combination of thin film transistor technology and the active pixel sensor may become the future trend of a large-size image sensor. The combination of the active pixel sensor and the thin film transistor can amplify the input signal, improve the signal-to-noise ratio, and be compatible with analog multiplexer (MUX) function. On the other hand, with the faster response speed of low temperature polysilicon (LTPS), high frame rate and low dose can be achieved, which can greatly improve the application scenario and market recognition.

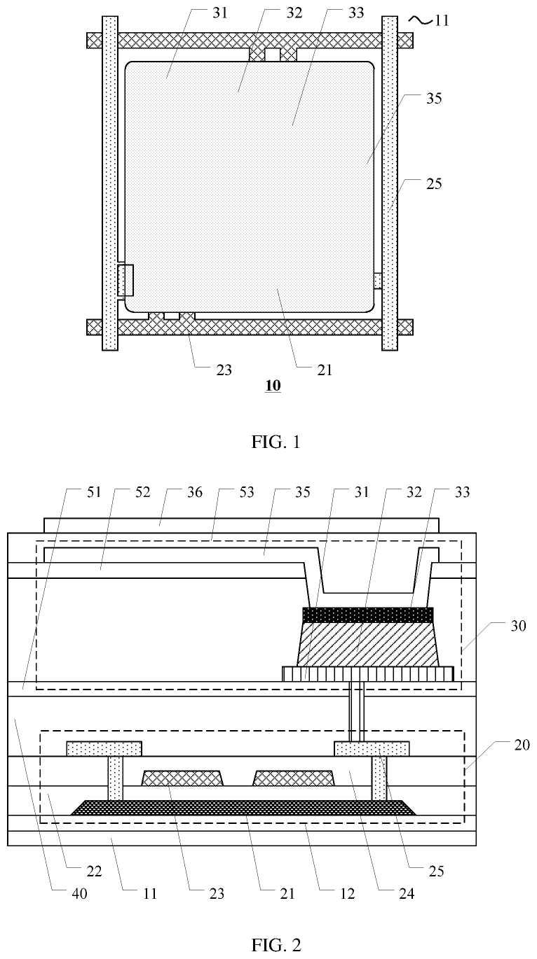

FIG. 1 is a schematic plan view of a photoelectric sensor; FIG. 2 is a schematic cross-sectional view of the photoelectric sensor shown in FIG. 1. As illustrated by FIGS. 1 and 2, the photoelectric sensor 10 includes a base substrate 11, a driving circuit 20, and a photoelectric converter 30; the driving circuit 20 is located on the base substrate 11, and the photoelectric converter 30 is located on a side of the driving circuit 20 away from the base substrate 11; the driving circuit 20 may include an active layer 21, a gate insulating layer 22, a gate electrode layer 23, an interlayer insulating layer 24, and a first conductive layer 25 which are sequentially stacked. All the above-mentioned four layers need to be patterned, so four exposure processes are required. The photoelectric sensor 10 further includes a planarization layer 40 and a first passivation layer 51, which are located between the driving circuit 20 and the photoelectric converter 30 to separate the driving circuit 20 from the photoelectric converter 30. The photoelectric converter 30 includes a first electrode 31, a photoelectric conversion layer 32, a conductive protection layer 33, an insulating layer 34, a second passivation layer 52, a second electrode 35, a third passivation layer 53 and an electrostatic protection layer 36. The photoelectric conversion layer 32 needs three exposure processes, the first electrode 31, the conductive protection layer 33, the second electrode layer 35 and the electrostatic protection layer 36 need four exposure processes, and the insulating layer 34 and the second passivation layer 52 need to form via holes, so two exposure processes are also needed. The photoelectric sensor adopts 13 exposure processes, resulting in relatively high cost.

In this regard, embodiments of the present disclosure provide a photoelectric sensor, an image sensor and an electronic device. The photoelectric sensor includes a base substrate, a driving circuit and a photoelectric converter. The driving circuit and the photoelectric converter are both located on the base substrate; the photoelectric converter includes a first electrode and a photoelectric conversion layer, the photoelectric conversion layer is located at a side of the first electrode away from the base substrate; the driving circuit includes a reset sub-circuit, the reset sub-circuit includes a first source electrode and a first drain electrode, and the first electrode and the first drain electrode are integrated into the same electrode and arranged in the same layer as the first source electrode. Therefore, by arranging and connecting the first drain electrode of the reset sub-circuit and the first electrode of the photoelectric converter in the same layer, the photoelectric sensor can save a plurality of film structures and a plurality of exposure processes, and further reduce the cost and the volume of the photoelectric sensor.

Hereinafter, the photoelectric sensor, the image sensor and the electronic device provided by the embodiments of the present disclosure will be described in detail with reference to the accompanying drawings.

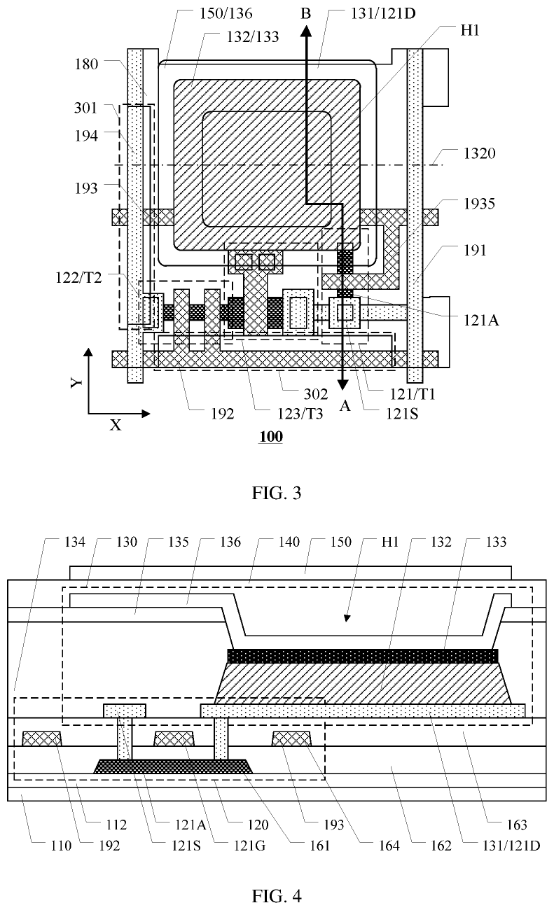

An embodiment of the present disclosure provides a photoelectric sensor. FIG. 3 is a schematic plan view of a photoelectric sensor according to an embodiment of the present disclosure; FIG. 4 is a schematic cross-sectional view of a photoelectric sensor provided by an embodiment of the present disclosure along a line AB in FIG. 3.

As illustrated by FIGS. 3 and 4, the photoelectric sensor 100 includes a base substrate 110, a driving circuit 120, and a photoelectric converter 130; the driving circuit 120 is located on the base substrate 110, and the photoelectric converter 130 is located on the base substrate 110; the photoelectric converter 130 includes a first electrode 131 and a photoelectric conversion layer 132, and the photoelectric conversion layer 132 is located at a side of the first electrode 131 away from the base substrate 110. The driving circuit 120 includes a reset sub-circuit 121, the reset sub-circuit 121 includes a first source electrode 121S and a first drain electrode 121D, the first electrode 131 and the first drain electrode 121D are integrated into a same electrode, and are arranged in the same layer as the first source electrode 121S.

In the photoelectric sensor provided by the embodiment of the present disclosure, the first electrode and the first drain electrode are integrated into the same electrode and arranged in the same layer as the first source electrode. By arranging the first drain electrode of the reset sub-circuit and the first electrode of the photoelectric converter in the same layer and connecting the first drain electrode and the first electrode into a whole (equivalent to the first drain electrode of the reset sub-circuit also being reused as the first electrode of the photoelectric converter), the photoelectric sensor can save a plurality of film structures and a plurality of exposure processes, thus reducing the cost and the volume of the photoelectric sensor. For example, the planarization layer and the passivation layer between the driving circuit and the photoelectric converter and a film layer where the first electrode is located can be saved.

In some examples, as illustrated by FIG. 3, an orthographic projection of the first electrode 131 of the photoelectric converter 130 on the base substrate 110 is spaced apart from an orthographic projection of the first source electrode 121S on the base substrate 110; that is, the first electrode 131 of the photoelectric converter 130 does not overlap with the first source electrode 121S. Therefore, in the case where the first drain electrode 121D of the reset sub-circuit 121 and the first electrode 131 of the photoelectric converter 130 are arranged in the same layer and connected as a whole, the first source the first source electrode 121S arranged in the same layer as the first electrode 131 will not hinder the arrangement of the first electrode 131. Therefore, the first electrode 131 or the first drain electrode 121 in the photoelectric sensor can have a larger area, thus meeting the design requirements and preventing the photoelectric sensor from saturating in advance.

In some examples, as illustrated by FIG. 3, in the photoelectric sensor 100, the reset sub-circuit 121 includes a reset transistor T1, and the reset transistor T1 includes a first active layer 121A. The overlapping area of an orthographic projection of the photoelectric conversion layer 132 on the base substrate 110 and an orthographic projection of the first active layer 121A on the base substrate 110 is less than ½ of an area of the orthographic projection of the first active layer 121A on the base substrate 110. Therefore, in the photoelectric sensor 100, the overlapping area of the photoelectric conversion layer 132 and the driving circuit 120 is relatively small, so that it is convenient to form the first electrode 131 or the first drain electrode 121D of the reset sub-circuit with a relatively large area, thereby meeting the design requirements and preventing the photoelectric sensor from saturating in advance.

Furthermore, in the photoelectric sensor 100, the reset sub-circuit 121 includes a reset transistor T1, the reset transistor T1 includes a first active layer 121A, the overlapping area of the orthographic projection of the photoelectric conversion layer 132 on the base substrate 110 and the orthographic projection of the first active layer 121A on the base substrate 110 is less than ⅓ of the area of the orthographic projection of the first active layer 121A on the base substrate 110. Therefore, in the photoelectric sensor 100, the overlapping area of the photoelectric conversion layer 131 and the driving circuit 120 is relatively small, which facilitates the formation of the first electrode 131 with relatively large area or the first drain electrode 121D of the reset sub-circuit with relatively large area.

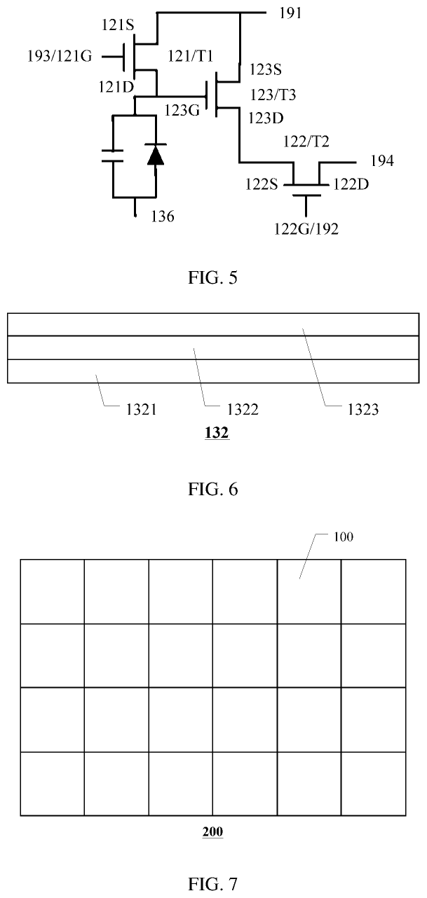

FIG. 5 is an equivalent schematic diagram of a driving circuit in a photoelectric sensor according to an embodiment of the present disclosure. As illustrated by FIGS. 3 and 5, the driving circuit 120 further includes a signal reading sub-circuit 122 and a signal amplifying sub-circuit 123. An orthographic projection of the signal reading sub-circuit 122 on the base substrate 110, an orthographic projection of the signal amplifying sub-circuit 123 on the base substrate 110 and an orthographic projection of the reset sub-circuit 121 on the base substrate 110 are sequentially arranged along the first direction X, and the driving circuit 120 and the photoelectric converter 130 are sequentially arranged along the second direction Y. Therefore, the photoelectric sensor can provide a “coplanar” design of the driving circuit and the photoelectric sensor, improve the integration of the driving circuit, and reduce the area occupied by the driving circuit, thereby facilitating the formation of the first electrode 131 with relatively large area or the first drain electrode 121D of the reset sub-circuit with relatively large area, thus meeting the design requirements and preventing the photoelectric sensor from saturating in advance.

In some examples, as illustrated by FIG. 3, the photoelectric conversion layer 132 includes a bisector 1320 extending in the first direction, and the driving circuit 120 is located at a side of the bisector 1320 in the second direction. It should be noted that the bisector mentioned above refers to an area bisector of the orthographic projection of the photoelectric conversion layer on the base substrate.

For example, according to the measured data: when the illumination intensity is 10 w lux and the pixel pitch is 70 μm, the accumulated charge of the pixel is about 220 fc, which can be calculated as 0.05 (fc/μm²) of the photoelectric sensor per unit area. Generally, a linear voltage range of the active pixel sensor (APS) is 1.5 V. According to C=Q/U, taking U=1.5V, the minimum capacitance of photoelectric conversion layer (such as photodiode) required by active pixel sensor (APS) can be calculated. According to the dielectric constant of film, the minimum area of photoelectric conversion layer required is about 1600 μm². According to the actual layout design of the photoelectric sensor provided by the embodiment of the present disclosure, the design that the area of the photoelectric conversion layer is equal to 1600 μm² can be satisfied upon the pixel pitch being 70 μm. It should be noted that the above pixel pitch can be regarded as a size of an edge length of a square region occupied by one photoelectric sensor.

In some examples, as illustrated by FIGS. 3 and 5, the reset sub-circuit 121 further includes a first control electrode 121G, the signal reading sub-circuit 122 includes a second control electrode 122G, a second source electrode 122S and a second drain electrode 122D, and the signal amplifying sub-circuit 123 includes a third control electrode 123G, a third source electrode 123S and a third drain electrode 123D, and the third drain electrode 123D is connected with the second source electrode 122S, and the first drain electrode 121D is connected with the third control electrode 123G.

In some examples, as illustrated by FIGS. 3 and 5, the photoelectric sensor 100 further includes a power supply line 191, a data reading control line 192, a reset control line 193, and a data signal line 194; the power line 191 extends in the second direction Y and is configured to be connected with the first source electrode 121S and the third source electrode 123S; the read control line 192 extends in the first direction X and is configured to be connected with the second control electrode 122G; the reset control line 193 extends in the first direction X and is configured to be connected with the first control electrode 121G; the data signal line 194 extends in the second direction Y and is configured to be connected with the second drain electrode 122D. Therefore, the reset sub-circuit can reset the first electrode 131 of the photoelectric converter 130 by using the power supply voltage (e.g., VDD) provided by the power supply line 191; the signal amplifying circuit 123 can amplify the voltage generated by the photoelectric conversion layer 132 by using the power supply voltage provided by the power supply 191; the data reading sub-circuit 122 can read out the voltage amplified by the signal amplifying sub-circuit 123.

In some examples, as illustrated by FIGS. 3 and 5, the reset sub-circuit 121 may be a reset transistor T1, the signal amplifying sub-circuit 123 may be a signal amplifying transistor T3, and the data reading sub-circuit 122 may be a data reading transistor T2. The reset transistor T1 includes a first active layer 121A, the data reading transistor T2 includes a second active layer 122A, and the signal amplifying transistor T3 includes a third active layer 123A. The materials of the first active layer 121A, the second active layer 122A and the third active layer 123A are low temperature polysilicon (LTPS), so that the reset transistor T1, the data reading transistor T2 and the signal amplifying transistor T3 have faster response speed and higher carrier mobility.

In some examples, as illustrated by FIG. 3, an orthographic projection of the second active layer 122A on the base substrate 110 is spaced from an orthographic projection of the photoelectric conversion layer 132 on the base substrate 110, that is, the second active layer 122A does not overlap with the photoelectric conversion layer 132; an orthographic projection of the third active layer 123A on the base substrate 110 is spaced from the orthographic projection of the photoelectric conversion layer 132 on the base substrate 110, that is, the third active layer 123A does not overlap with the photoelectric conversion layer 132.

Hereinafter, the working process of the driving circuit provided by the embodiment of the present disclosure will be briefly explained with reference to FIG. 5. In the driving circuit 120, the reset transistor T1 is used for resetting, the signal amplifying transistor T3 is used for amplifying the signal generated by the photoelectric converter 130, and the signal reading transistor T2 is used for reading the amplified signal. First, the reset signal line 193 applies a reset signal to the first control electrode 121G of the reset transistor T1 to turn-on the reset transistor T1. In this case, the third control electrode 123G of the signal amplifying transistor T3 is reset to the power supply signal (e.g., VDD) on the power supply line 191, and works in a saturated state. Then, the photoelectric converter 130 is illuminated to generate light leakage, and the light leakage causes the potential of the first electrode 131 of the photoelectric converter 130 to drop. Finally, the data reading control line 192 applies a gate signal to the second control electrode 122G of the signal reading transistor T2. In this case, the signal reading transistor T2 is turned-on, and a potential change on the third control electrode 123G of the signal amplifying transistor T3 is amplified by the signal amplifying transistor T3 and read out by the data line 194. It should be noted that the embodiments of the present disclosure include, but are not limited thereto, and the driving circuit can also adopt other suitable structures and other suitable working processes.

In some examples, as illustrated by FIGS. 3 and 5, an orthographic projection of the reset control line 193 on the base substrate 110 partially overlaps with an orthographic projection of the photoelectric conversion layer 132 on the base substrate 110; the photoelectric conversion layer 132 includes a bisector 1320 extending in the first direction, and the reset control line 193 is located at a side of the bisector 1320 close to the data reading control line 192.

In some examples, as illustrated by FIGS. 3 and 5, the photoelectric sensor 100 further includes a reset connection block 1935, the reset connection block 1935 extends in the second direction and is located between the power line 191 and the photoelectric conversion layer 132; the reset connection block 1935 is connected with the reset control line 193 and the first control electrode 121G, respectively.

In some examples, as illustrated by FIGS. 3 and 5, the second active layer 122A and the third active layer 123A both extend in the first direction; the first active layer 121A extends in the second direction.

For example, the first direction and the second direction are perpendicular to each other; it should be noted that, the above mentioned “perpendicular to each other” includes a case that the first direction and the second direction are completely perpendicular, and also includes a case that an angle between the first direction and the second direction being 80 to 100 degrees.

In some examples, as illustrated by FIGS. 3 and 4, the driving circuit 120 includes an active layer 161, a gate insulating layer 162, a gate electrode layer 163, an interlayer insulating layer 163, and a source drain metal layer 164 which are sequentially arranged. The first active layer 121A of the reset transistor T1, the second active layer 122A of the data reading transistor T2 and the third active layer 123A of the data amplifying transistor T3 may all be located on the active layer 161. The first source electrode 121S and the first drain electrode 121D of the reset transistor T1 are both located in the source drain metal layer 164.

In some examples, as illustrated by FIG. 3, the data reading transistor T2 can adopt a double-gate structure, so that the performance can be improved. Of course, the embodiments of the present disclosure include but are not limited thereto, and the data reading transistor can also adopt other structures.

In some examples, as illustrated by FIG. 4, the photoelectric sensor 100 further includes a conductive protection layer 133, an insulating layer 134, a first passivation layer 135 and a second electrode 136; the conductive protection layer 133 is located at a side of the photoelectric conversion layer 132 away from the first electrode 131; the insulating layer 134 is located at a side of the conductive protection layer 133 away from the base substrate 110; the first passivation layer 135 is located at a side of the insulating layer 134 away from the conductive protection layer 133; the second electrode 136 is located at a side of the first passivation layer 135 away from the base substrate 110. The photoelectric sensor 100 further includes a via hole H1, the via hole H1 is located in the insulating layer 134 and the first passivation layer 135, and the second electrode 136 is connected with the conductive protection layer 133 through the via hole H1. Therefore, the conductive protection layer 133 can be used as a protection layer of the photoelectric conversion layer 132; and the insulating layer 134 and the first passivation layer 135 can be used as planarization layers, so that the second electrode 136 formed on the insulating layer 134 and the first passivation layer 135 have better flatness.

In some examples, as illustrated by FIGS. 3 and 4, the second electrode 136 includes a first hollow portion 301, and an orthographic projection of the first hollow portion 301 on the base substrate 110 at least partially overlaps with an orthographic projection of the data signal line 194 on the base substrate 110; and a second hollow portion 302, an orthographic projection of the second hollow portion 302 on the base substrate 110 at least partially overlaps with an orthographic projection of the data reading control line 192 on the base substrate 110. Therefore, by arranging the first hollow portion and the second hollow portion, the load on the data signal line and the data reading control line can be reduced, and the performance of the photoelectric sensor can be improved.

In some examples, a size range of the first hollow portion 301 in the first direction is 8 to 10 microns, a size range of the first hollow portion 301 in the second direction is 40 to 46 microns, a size range of the second hollow portion 302 in the first direction is 50 to 58 microns, and a size range of the second hollow portion 302 in the second direction is 8 to 10 microns. It should be noted that, the embodiments of the present disclosure include but are not limited thereto, and the sizes of the first hollow portion and the second hollow portion can be set according to actual needs.

In some examples, as illustrated by FIGS. 3 and 4, the area of the orthographic projection of the via hole H1 on the base substrate 110 is greater than 50% of the area of the orthographic projection of the photoelectric conversion layer 132 on the base substrate 110, so that the electrical connection between the photoelectric conversion layer 132 and the second electrode 136 can be enhanced.

For example, the conductive protection layer 133 and the photoelectric conversion layer 132 can be patterned with a same mask, thus saving the mask process. At this time, a shape of an orthographic projection of the conductive protection layer 133 on the base substrate 110 is the same as that of the photoelectric conversion layer 132 on the base substrate 110; or, the orthographic projection of the conductive protection layer 133 on the base substrate 110 is slightly smaller than that of the photoelectric conversion layer 132 on the base substrate 110. For example, the shortest distance between an edge of the orthographic projection of the conductive protection layer 133 on the base substrate 110 and an edge of the orthographic projection of the photoelectric conversion layer 132 on the base substrate 110 is about 0.5 microns.

For example, a material of the insulating layer 134 may be resin. Of course, the embodiments of the present disclosure include but are not limited thereto, and the insulating layer 134 can also be made of other materials.

For example, a material of the first passivation layer 135 can be selected from one or more of silicon oxide, silicon nitride or silicon oxynitride.

In some examples, as illustrated by FIGS. 3 and 4, the orthographic projection of the photoelectric conversion layer 132 on the base substrate 110 falls within the range of the orthographic projection of the first electrode 131 on the base substrate 110; the area of the orthographic projection of the photoelectric conversion layer 132 on the base substrate 110 is smaller than the area of the orthographic projection of the first electrode 131 on the base substrate 110, so that the flatness of the photoelectric conversion layer 132 formed at a side of the first electrode 131 away from the base substrate 110 can be improved, thereby improving the performance of the photoelectric converter 130.

In some examples, as illustrated by FIGS. 3 and 4, the area of the orthographic projection of the conductive protection layer 133 on the base substrate 110 is smaller than the area of the orthographic projection of the photoelectric conversion layer 132 on the base substrate 110 and the area of the orthographic projection of the first electrode 131 on the base substrate 110.

In some examples, as illustrated by FIG. 4, the photoelectric sensor 100 further includes a second passivation layer 140 and an electrostatic protection layer 150; the second passivation layer 140 is located at a side of the second electrode 136 away from the base substrate 110; the electrostatic protection layer 150 is located at a side of the second passivation layer 140 away from the second electrode 136. Therefore, the electrostatic protection layer 150 can prevent static electricity, thus improving the safety and stability of the photoelectric sensor.

In some examples, as illustrated by FIG. 4, an orthographic projection of the electrostatic protection layer 150 on the base substrate 110 completely overlaps with an orthographic projection of the second electrode 136 on the base substrate 110. Therefore, the electrostatic protection layer 150 and the second electrode 136 can be formed by a same mask, thereby saving one mask.

For example, a material of the conductive protection layer 133 may be a transparent conductive oxide, such as indium tin oxide (ITO); a material of the second electrode 136 may be a transparent conductive oxide, such as indium tin oxide (ITO). Of course, the embodiments of the present disclosure include but are not limited thereto, and other suitable materials can also be used for the conductive protection layer and the second electrode.

For example, a material of the electrostatic protection layer 150 may be a transparent conductive oxide, such as indium tin oxide (ITO). Of course, the embodiments of the present disclosure include, but are not limited thereto, and the electrostatic protection layer 150 may also adopt other suitable materials.

FIG. 6 is a schematic diagram of a photoelectric conversion layer provided by an embodiment of the present disclosure. As illustrated by FIG. 6, the photoelectric conversion layer 132 includes an N-type semiconductor layer 1321, an intrinsic semiconductor layer 1322, and a P-type semiconductor layer 1323. That is, the photoelectric conversion layer 132 adopts a photodiode with a PIN structure.

An embodiment of the present disclosure also provides an image sensor. FIG. 7 is a schematic diagram of an image sensor according to an embodiment of the present disclosure. As illustrated by FIG. 7, the image sensor 200 includes a plurality of photoelectric sensors 100, and each of the photoelectric sensors 100 can be a photoelectric sensor 100 provided by any one of the above examples. Therefore, in the photoelectric sensor, the first drain electrode of the reset sub-circuit and the first electrode of the photoelectric converter can be arranged on the same layer and connected into a whole, so that a plurality of film structures and a plurality of exposure processes can be saved, and the cost and the volume of the photoelectric sensor can be reduced. Therefore, the image sensor has relatively low cost, relatively small volume and relatively high performance.

In some examples, as illustrated by FIG. 7, the plurality of photoelectric sensors 100 are arranged in an array, so that upon the image sensor 200 being irradiated by light, the signals generated by all the photoelectric sensors can be conveniently combined to form a complete image.

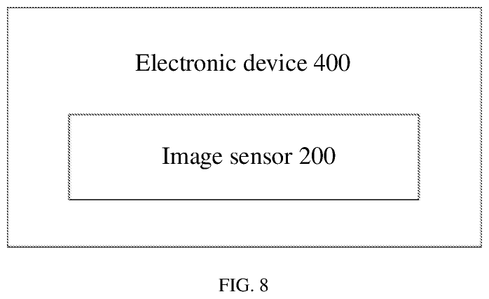

An embodiment of the present disclosure also provides an electronic device. FIG. 8 is a schematic diagram of an electronic device provided by an embodiment of the present disclosure. As illustrated by FIG. 8, the electronic device 400 includes the above-mentioned image sensor 200. Therefore, the electronic device also has relatively low cost, relatively small volume and relatively high performance.

For example, the electronic device can be a smart phone, a tablet computer, a notebook computer, a navigator, a smart camera and other electronic devices with shooting functions.

The following points need to be explained:
(1) In the drawings of the embodiments of the present disclosure, only the structures related to the embodiments of the present disclosure are involved, and other structures can refer to the general design.
(2) The features of the same embodiment and different embodiments of the present disclosure can be combined with each other without conflict.

The above is only an exemplary embodiment of the present disclosure, and it is not intended to limit the scope of protection of the present disclosure, which is determined by the appended claims.

1. A photoelectric sensor, comprising:
a base substrate;
a driving circuit, located on the base substrate;
a photoelectric converter, located on the base substrate,
wherein the photoelectric converter comprises a first electrode and a photoelectric conversion layer, and the photoelectric conversion layer is located at a side of the first electrode away from the base substrate,
the driving circuit comprises a reset sub-circuit, the reset sub-circuit comprises a first source electrode and a first drain electrode, the first electrode and the first drain electrode are integrated into a same electrode and arranged in a same layer as the first source electrode.

2. The photoelectric sensor according to claim 1, wherein an orthographic projection of the first electrode of the photoelectric converter on the base substrate is spaced apart from an orthographic projection of the first source electrode on the base substrate.

3. The photoelectric sensor according to claim 1, wherein the reset sub-circuit comprises a reset transistor, and the reset transistor comprises a first active layer, and an overlapping area of an orthographic projection of the photoelectric conversion layer and an orthographic projection of the first active layer on the base substrate is less than ½ of an area of the orthographic projection of the first active layer on the base substrate.

4. The photoelectric sensor according to claim 1, wherein an orthographic projection of the photoelectric conversion layer on the base substrate falls within a range of an orthographic projection of the first electrode on the base substrate.

5. The photoelectric sensor according to claim 1, wherein the driving circuit further comprises a signal reading sub-circuit and a signal amplifying sub-circuit,
an orthographic projection of the signal reading sub-circuit on the base substrate, an orthographic projection of the signal amplifying sub-circuit on the base substrate and an orthographic projection of the reset sub-circuit on the base substrate are sequentially arranged in a first direction, and an orthographic projection of the driving circuit on the base substrate and an orthographic projection of the photoelectric converter on the base substrate are sequentially arranged in a second direction.

6. The photoelectric sensor according to claim 5, wherein the signal reading sub-circuit comprises a signal reading transistor, the signal amplifying sub-circuit comprises a signal amplifying transistor, the signal reading transistor comprises a second active layer, the signal amplifying transistor comprises a third active layer,
an orthographic projection of the second active layer on the base substrate is spaced apart from an orthographic projection of the photoelectric converter on the base substrate, and an orthographic projection of the third active layer on the base substrate is spaced apart from the orthographic projection of the photoelectric converter on the base substrate.

7. The photoelectric sensor according to claim 5, wherein the photoelectric conversion layer comprises a bisector extending in the first direction, and the driving circuit is located at a side of the bisector in the second direction.

8. The photoelectric sensor according to claim 5, wherein the reset sub-circuit further comprises a first control electrode, the signal reading sub-circuit comprises a second control electrode, a second source electrode and a second drain electrode, and the signal amplifying sub-circuit comprises a third control electrode, a third source electrode and a third drain electrode,
the third drain electrode is connected with the second source electrode, and the first drain electrode is connected with the third control electrode.

9. The photoelectric sensor according to claim 5, further comprising:
a power line, extending in the second direction and configured to be connected with the first source electrode and the third source electrode;
a data reading control line, extending in the first direction and configured to be connected with the second control electrode;
a reset control line, extending in the first direction and configured to be connected with the first control electrode; and
a data signal line, extending in the second direction and configured to be connected with the second drain electrode.

10. The photoelectric sensor according to claim 9, wherein an orthographic projection of the reset control line on the base substrate partially overlaps with an orthographic projection of the photoelectric conversion layer on the base substrate,
the photoelectric conversion layer comprises a bisector extending in the first direction, and the reset control line is located at a side of the bisector close to the data reading control line.

11. The photoelectric sensor according to claim 10, further comprising:
a reset connection block, extending along the second direction and located between the power line and the photoelectric conversion layer,
wherein the reset connection block is respectively connected with the reset control line and the first control electrode.

12. The photoelectric sensor according to claim 9, wherein the photoelectric converter further comprises:
a conductive protection layer, located at a side of the photoelectric conversion layer away from the first electrode;
an insulating layer, located at a side of the conductive protection layer away from the base substrate;
a first passivation layer, located at a side of the insulating layer away from the conductive protection layer; and
a second electrode, located at a side of the first passivation layer away from the base substrate,
wherein the photoelectric sensor further comprises a via hole located in the insulating layer and the first passivation layer, and the second electrode is connected with the conductive protection layer through the via hole.

13. The photoelectric sensor according to claim 12, wherein the second electrode comprises:
a first hollow portion, wherein an orthographic projection of the first hollow portion on the base substrate at least partially overlaps with an orthographic projection of the data signal line on the base substrate; and
a second hollow portion, wherein an orthographic projection of the second hollow portion on the base substrate at least partially overlaps with an orthographic projection of the data reading control line on the base substrate.

14. The photoelectric sensor according to claim 13, wherein a size range of the first hollow portion in the first direction is 8 to 10 microns, and a size range of the first hollow portion in the second direction is 40 to 46 microns,
a size range of the second hollow portion in the first direction is 50 to 58 microns, and a size range of the second hollow portion in the second direction is 8 to 10 microns.

15. The photoelectric sensor according to claim 12, further comprising:
a second passivation layer, located at a side of the second electrode away from the base substrate; and
an electrostatic protection layer, located at a side of the second passivation layer away from the second electrode.

16. The photoelectric sensor according to claim 12, wherein a material of the conductive protection layer is a transparent conductive oxide, and a material of the second electrode is a transparent conductive oxide.

17. The photoelectric sensor according to claim 1, wherein the photoelectric conversion layer comprises an N-type semiconductor layer, an intrinsic semiconductor layer and a P-type semiconductor layer which are stacked in order.

18. An image sensor, comprising a plurality of photoelectric sensors, wherein each of the photoelectric sensors is the photoelectric sensor according to claim 1.

19. The image sensor according to claim 18, wherein the plurality of photoelectric sensors are arranged in an array.

20. An electronic device, comprising the image sensor according to claim 18.
